(19) United States
(12) Patent Application Publication
(10) Pub. No.: US 2021/0310862 A1
(43) Pub. Date: Oct. 7, 2021

(54) LASER ENERGY MEASURING DEVICE, AND LASER ENERGY MEASURING METHOD

(71) Applicant: V TECHNOLOGY CO., LTD., Yokohama-shi, Kanagawa (JP)

(72) Inventor: Michinobu Mizumura, Yokohama-shi, Kanagawa (JP)

(21) Appl. No.: 17/264,026

(22) PCT Filed: Jun. 12, 2019
(86) PCT No.: PCT/JP2019/023234

§ 371 Date: Jan. 28, 2021

(30) Foreign Application Priority Data
Jul. 30, 2018 (JP) 2018-142967

(51) Int. Cl. G01J 1/42; G01J 4/04; G01J 1/04

(52) U.S. Cl. CPC G01J 1/4257; G01J 4/04; H01L 27/1285; G01J 1/0429; G01J 1/0414

(57) ABSTRACT

A laser energy measuring device with which laser light radiated onto a substrate can be evaluated accurately. The laser energy measuring device includes: inside or outside an illuminating optical system, a first beam splitter which reflects laser light by any one of P-polarized reflection and S-polarized reflection; a second beam splitter which performs the other of P-polarized reflection and S-polarized reflection with respect to first reflected light reflected by the first beam splitter; a first measuring unit which measures energy of second reflected light reflected by the second beam splitter; and a second measuring unit which measures energy of transmitted light that has been transmitted through the second beam splitter.

### TECHNICAL FIELD

This disclosure relates to a laser energy measuring device and a laser energy measuring method.

### BACKGROUND

Conventionally, a laser irradiating device that forms a thin film on a substrate by enlarging laser light radiated from a light source using an illuminating optical system and irradiating the substrate with the enlarged laser light is known. As such a laser irradiating device, Japanese Unexamined Patent Application Publication No. 2005-101202 discloses a configuration in which laser light is polarized and radiated.

In the laser irradiating device, for example, reflected light reflected by P-polarized reflection inside the illuminating optical system is further reflected by S-polarized reflection and, thus, an output thereof is evaluated. However, in that example, since the polarization component is canceled, a change in output from the light source can be evaluated on the basis of a change in the output of the reflected light, but there is a problem that polarization characteristics inside the illuminating optical system cannot be evaluated.

It could, therefore, be helpful to provide a laser energy measuring device with which laser light radiated onto a substrate can be accurately evaluated by simultaneously evaluating an output from a light source and polarization characteristics inside an illuminating optical system.

### SUMMARY

I thus provide:

A laser energy measuring device including: inside or outside an illuminating optical system, a first beam splitter which reflects laser light by means of any one of P-polarized reflection and S-polarized reflection; a second beam splitter which performs the other of P-polarized reflection and S-polarized reflection with respect to first reflected light reflected by the first beam splitter; a first measuring unit which measures energy of second reflected light reflected by the second beam splitter; and a second measuring unit which measures energy of transmitted light that has been transmitted through the second beam splitter.

The second beam splitter may perform, among the P-polarized reflection and the S-polarized reflection, the P-polarized reflection with respect to the first reflected light.

A laser energy measuring method including: inside or outside an illuminating optical system, a first polarization step of reflecting laser light reflected by means of any one of P-polarized reflection and S-polarized reflection; a second polarization step of performing the other of P-polarized reflection and S-polarized reflection with respect to first reflected light reflected in the first polarization step; a first measuring step of measuring energy of second reflected light reflected in the second polarization step; and a second polarization step of measuring energy of transmitted light that has been transmitted in the second polarization step.

The laser energy measuring device includes the first measuring unit and the second measuring unit. For this reason, the first measuring unit can evaluate an output from a light source in which a polarization component is canceled, and the second measuring unit can evaluate polarization characteristics inside the illuminating optical system. Using these results, it is possible to accurately evaluate the laser light radiated onto the substrate.

### BRIEF DESCRIPTION OF THE DRAWINGS

FIG. 1 is a block diagram of a laser irradiating device and a laser energy measuring device according to an example.

FIGS. 2(a)-2(g) are diagrams illustrating various states of polarization of laser light.

### DETAILED DESCRIPTION

Hereinafter, examples of my devices and methods will be described with reference to the drawings.

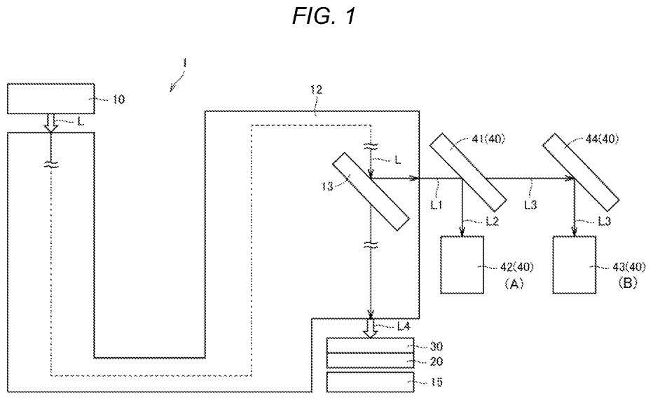

FIG. 1 is a block diagram of a laser irradiating device 1 and a laser energy measuring device 40 according to an example. Also, in FIG. 1, since various configurations are assumed for an internal configuration of an illuminating optical system 12, illustration thereof will be omitted.

As shown in FIG. 1, the laser irradiating device 1 includes a light source 10 that generates laser light L, the illuminating optical system 12, a projection lens 20, and a projection mask 30. The laser irradiating device 1 is, for example, a device that irradiates a region in which a channel region is planned to be formed on a substrate 15 with laser light to perform annealing and polycrystallizing the region in which the channel region is planned to be formed in a manufacturing process of a semiconductor device such as a thin film transistor (TFT).

The laser irradiating device 1 is used, for example, at the time of forming a thin film transistor of pixels such as a peripheral circuit of a liquid crystal display device. When such a thin film transistor is formed, first, a gate electrode made of a metal film such as Al is patterned on the substrate 15 by sputtering. Then, a gate insulating film made of a SiN film is formed on the entire surface of the substrate 15 using a low temperature plasma chemical vapor deposition (CVD) method.

Then, an amorphous silicon thin film is formed on the gate insulating film using, for example, a plasma CVD method. That is, the amorphous silicon thin film is formed (adhered) on the entire surface of the substrate 15. Finally, a silicon dioxide (SiO₂) film is formed on the amorphous silicon thin film.

Then, the laser irradiating device 1 illustrated in FIG. 1 irradiates a predetermined region (a region serving as the channel region in the thin film transistor) on the gate electrode of the amorphous silicon thin film with laser light to perform annealing, and polycrystallizes the predetermined region to makes it polysilicon. Also, as the substrate 15, for example, a glass substrate or the like can be adopted, but it does not necessarily have to be a glass material and any material such as a resin substrate formed of a material such as a resin may be adopted.

As shown in FIG. 1, in the laser irradiating device 1, a beam system of the laser light L radiated from the light source 10 is expanded by the illuminating optical system 12 and, thus, the brightness distribution is made uniform.

A first beam splitter 13 is provided inside the illuminating optical system 12. The first beam splitter 13 reflects and transmits the laser light L by either P-polarized reflection or S-polarized reflection. Thus, first reflected light L1 is generated. In this example, the first beam splitter 13 performs P-polarized reflection. Also, the first beam splitter 13 may be provided outside the illuminating optical system 12.

Further, a component of the laser light L transmitted through the first beam splitter 13 is radiated onto the substrate 15 as irradiation light L4 through the projection lens 20.

The light source 10 is, for example, an excimer laser that radiates the laser light L having a wavelength of 308 nm or 248 nm at a predetermined repeating cycle. Also, the wavelength is not limited to these examples and may be any wavelength. Then, the irradiation light L4 is transmitted through the projection mask 30 provided on the projection lens (a micro lens array) 20, separated into a plurality of laser lights, and radiated to a predetermined region of the amorphous silicon thin film coated on the substrate 15. When the irradiation light L4 is radiated to the predetermined region of the amorphous silicon thin film coated on the substrate 15, the amorphous silicon thin film is instantaneously heated and melted to become a polysilicon thin film.

Also, although an example in which the micro lens array is used as the projection lens 20 has been described, it is not always necessary to use the micro lens array and a single lens may be used as the projection lens 20. The projection mask 30 through which the laser light L is transmitted is disposed on the projection lens 20.

Next, the laser energy measuring device 40 that evaluates an output of the laser irradiating device 1 described above will be described.

As shown in FIG. 1, the laser energy measuring device 40 includes a second beam splitter 41, a first measuring unit 42, and a second measuring unit 43. The second beam splitter 41 performs, among P-polarized reflection and S-polarized reflection, polarized reflection different from that of the first beam splitter 13 with respect to the first reflected light L1 to generate second reflected light L2 and transmitted light L3. In this example, the second beam splitter 41 performs S-polarized reflection.

In this example, the first beam splitter 13 and the second beam splitter 41 are glass plates and inevitably have polarization characteristics in a process of separating the first reflected light L1 from the laser light L. The first measuring unit 42 measures energy of the second reflected light L2, and the second measuring unit 43 measures energy of the transmitted light L3.

Further, the laser energy measuring device 40 includes a mirror 44. The mirror 44 reflects the transmitted light L3 and irradiates the second measuring unit 43 with the transmitted light. Also, the laser energy measuring device 40 does not have to include the mirror 44.

The laser energy measuring method according to this example includes a polarization step in which the first reflected light L1 is polarized by the second beam splitter 41, a first measurement step of measuring the second reflected light L2 using the first measuring unit 42, and a second measurement step of measuring the transmitted light L3 using the second measuring unit 43.

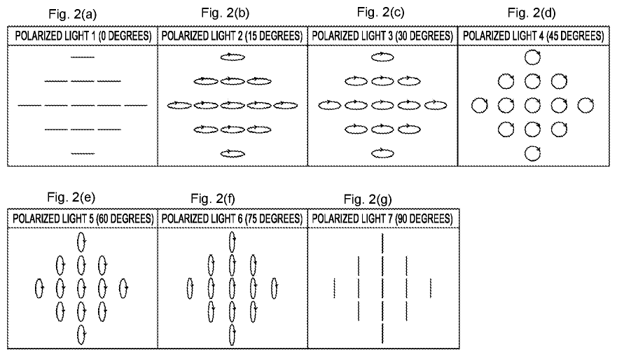

Next, measurement results using the laser energy measuring device 40 will be described. In this measurement, when P-polarized light of the laser light L from the light source 10 whose output target value is 100 [mJ] in a P-polarized state is disturbed due to distortion of the refractive index inside the laser or in the illuminating optical system 12 will be assumed to be each polarized state shown in FIGS. 2(a)-2(g).

Then, in each state, the energy was evaluated by the first measuring unit 42 and the second measuring unit 43. Further, on the basis of the measurement results obtained by each of the first measuring unit 42 and the second measuring unit 43, an output value P of the irradiation light L4 radiated onto the substrate 15 was calculated using the following known formula (1). The results are shown in Table 1.

P=a×A−(A+0.9A+B)

P: Output value of irradiation light L4 [mJ], a: Coefficient=455.4202 [−]
A: Output value of second reflected light L2 measured by first measuring unit 42 [mJ]
B: Output value of transmitted light L3 measured by second measuring unit 43 [mJ]

TABLE 1

| | | (P) | | (A) Second | | (B) | |
|---|---|---|---|---|---|---|---|
| | Beam | Irradiation | | reflected | | Transmitted | |
| | incidence | light L4 | | light L2 | | light L3 | |
| | [mJ] | [mJ] | Ratio | [mJ] | Ratio | [mJ] | Ratio |
| Polarized light 1 | 100.09 | 98.674 | 1.000 | 0.220 | 1.000 | 1.009 | 1.000 |
| Polarized light 2 | 100.09 | 98.128 | 0.994 | 0.220 | 1.000 | 1.550 | 1.537 |
| Polarized light 3 | 100.07 | 96.709 | 0.980 | 0.220 | 1.000 | 2.951 | 2.925 |
| Polarized light 4 | 100.08 | 91.592 | 0.928 | 0.220 | 0.999 | 8.062 | 7.992 |
| Polarized light 5 | 100.04 | 86.419 | 0.876 | 0.220 | 1.000 | 13.188 | 13.073 |
| Polarized light 6 | 100.04 | 85.001 | 0.861 | 0.220 | 1.000 | 14.599 | 14.472 |
| Polarized light 7 | 100.04 | 84.455 | 0.856 | 0.220 | 1.000 | 15.149 | 15.017 |

As shown in Table 1, the output value A of the second reflected light L2 measured by the first measuring unit 42 is a constant value regardless of a degree of polarization. That is, this means that the output from the light source 10 is constant. On the other hand, the output value B of the transmitted light L3 measured by the second measuring unit 43 changes depending on the degree of polarization. This means that the first reflected light L1 that is P-polarized by the first beam splitter 13 is measured as the transmitted light L3 without being S-polarized by the second beam splitter 41 so that the an energy fluctuation component due to the polarization disturbance in the illuminating optical system 12 can be evaluated.

Therefore, by checking the output value P of the irradiation light L4 calculated on the basis of values A and B, both the output of the light source 10 and the polarization disturbance in the illuminating optical system 12 have been evaluated.

For example, since the output value P of the irradiation light L4 in the polarized light 7 in Table 1 is 84.455 [mJ], this value can be brought close to a target value of 100 [mJ] in the absence of polarized light by adjusting the output of the light source 10.

As described above, the laser energy measuring device 40 according to this example includes the first measuring unit 42 and the second measuring unit 43. For this reason, the first measuring unit 42 can evaluate the output of the laser light in which a polarized light component is canceled, and the second measuring unit 43 can evaluate the output of the laser light in which the polarized light component remains. These results can be used to accurately evaluate the output of the laser light.

The above examples are typical configurations of this disclosure. Therefore, various modifications may be made to the above-described examples without departing from the spirit of the disclosure.

Although the configuration in which, for example, the first beam splitter 13 performs the P-polarized reflection and the second beam splitter 41 performs the S-polarized reflection has been described in the above-described example, this disclosure is not limited to such an aspect. That is, it is sufficient that the first beam splitter 13 and the second beam splitter 41 have different types of polarization reflection, and the first beam splitter 13 may perform the S-polarized reflection and the second beam splitter 41 may perform the P-polarized reflection.

Further, this disclosure is not limited to the above-mentioned modified examples, and these modified examples may be selected and appropriately combined, or other modifications may be applied.

1.-3. (canceled)

4. A laser energy measuring device comprising:
inside or outside an illuminating optical system,
a first beam splitter that reflects laser light by either P-polarized reflection or S-polarized reflection;
a second beam splitter that performs another of P-polarized reflection and S-polarized reflection with respect to first reflected light reflected by the first beam splitter;
a first measuring unit that measures energy of second reflected light reflected by the second beam splitter; and
a second measuring unit that measures energy of transmitted light that has been transmitted through the second beam splitter.

5. The laser energy measuring device according to claim 4, wherein the first beam splitter performs, among the P-polarized reflection and the S-polarized reflection, the P-polarized reflection with respect to the first reflected light.

6. A method of measuring laser energy inside or outside an illuminating optical system comprising:
a first polarization step of reflecting laser light reflected by any one of P-polarized reflection and S-polarized reflection;
a second polarization step of performing another of P-polarized reflection and S-polarized reflection with respect to first reflected light reflected in the first polarization step;
a first measuring step of measuring energy of second reflected light reflected in the second polarization step; and
a second polarization step of measuring energy of transmitted light that has been transmitted in the second polarization step.
